(19) United States
(12) Patent Application Publication
(10) Pub. No.: US 2003/0016116 A1
(43) Pub. Date: Jan. 23, 2003

(54) Method of depositing a thin metallic film and related apparatus

(76) Inventor: Charles A. Blaha, North Royalton, OH (US)

Correspondence Address: SUMMA & ALLAN, P.A., 11610 NORTH COMMUNITY HOUSE ROAD, SUITE 200, CHARLOTTE, NC, 28277, US

(21) Appl. No.: 09/910,973

(22) Filed: Jul. 23, 2001

(51) Int. Cl. H01C 3/04; H01C 7/02; H01C 7/04; G03F 7/16; G01B 7/16; G01L 1/00; H01L 35/28; C23C 14/32

(52) U.S. Cl. 338/2; 338/25; 430/314; 73/774; 136/224; 204/192.21

(57) ABSTRACT

A method of depositing a thin metal film using photolithography is disclosed. The method includes the deposition of a sacrificial metal layer on a substrate. Photolithography processing forms a pattern on the sacrificial metal layer that is removed prior to sputter deposition of the thin metal film.

### FEDERALLY-SPONSORED RESEARCH OR DEVELOPMENT

The development of this invention included support from NASA under contract NAS3-99184. The government may have certain rights in this invention.

### FIELD OF THE INVENTION

The present invention relates to a method of depositing thin metallic films in the fabrication of electronic devices. In particular the invention relates to depositing thin metallic films in the fabrication of transducers such as strain gauges and thermocouples.

### BACKGROUND OF THE INVENTION

Thin metallic films are used in many applications. They are used as protective coatings and as elements in electrical circuits and transducers among other uses. In some applications precise patterns of thin films are required. Strain gauges such as those described in U.S. Pat. Nos. 5,192,938; 4,680,858 and 4,287,772 are examples of devices incorporating patterned thin metallic films. Thermocouples such as those described in U.S. Pat. Nos. 4,795,498 and 5,356,485 provide additional examples.

For ease of description, the invention is discussed in relation to forming thin metallic films in the production of strain gauges. Those skilled in the art, however, will readily recognize the beneficial application of the invention in the manufacture of other thin film transducers.

Strain gauges of the type discussed in U.S. Pat. No. 5,192,938 are known and are commercially available. Such gauges consist of thin metallic films or foils arranged in a meandering grid pattern of relatively small resolution. These gauges are conventionally produced by etching the pattern out of a previously deposited thin metal film or depositing a thin metal film using a shadow mask.

Etching conventionally consists of depositing a thin film of a desired metal, masking a desired pattern on the metal then etching away the material that is not covered by the mask. Very often chemical etchants (e.g. acids) are used to etch the desired pattern.

Although these conventional methods produce functional transducers, they also have deficiencies that limit their commercial usefulness. For example, conventional etching often results in thin films having undercut or feathered edges. This can lead to loss of film or disruptions in the grid pattern and failure of the device. Chemical etching is often difficult depending upon the metal that is etched. For example, platinum is a very desirable metal for use in transducers but it is very difficult to etch. Auqa regia is most often used to chemically etch platinum but it tends to destroy the material used to create the mask thus destroying the grid pattern. Likewise, gold is etched with iodine which stains. Furthermore, conventionally etching a thin film pattern can be very time consuming and monitoring the progress of the deposition is difficult. In most situations, confirmation of a correct pattern occurs at the end of the process after the metal is etched. At that point, if the pattern is flawed it is difficult if not impossible to correct.

Shadow masking a pattern may be likened to stenciling. A mask having a defined pattern is placed over a substrate. A metal is deposited through the mask onto the substrate thereby producing a thin metallic film in a desired pattern.

Shadow masking has similar deficiencies. Conventional masks are rigid and thus this process is typically limited to depositing thin films on flat surfaces. The shadow masks should lay completely flat and sealed against the underlying substrate. Any variation allows the deposited metal to bleed or “shadow” under the mask which results in non-uniform and imprecise depositions. If fine line patterns (e.g., small size, high resolution) are required the bleeding of the metal could create a short between two lines. As with chemical etching, confirmation of a successful pattern is possible only after removal of the mask. If the pattern is flawed in any manner the entire process, including the time consuming deposition of the metal, must be repeated.

In some instances, the finished pattern of thin metallic film, whether etched or shadow masked, is then attached to a substrate by an epoxy-like material.

The drive for miniaturization in the electrical sensor industry demands thin metal film transducers that are beyond the capabilities of conventional methods. Furthermore, production processes demand a more efficient method for manufacturing thin film transducers. Accordingly, a need exists for an improved method of precisely and accurately depositing thin metallic films in small dimensions.

One possible avenue for developing such an improved method is photolithography. Photolithography is a technique commonly used in the manufacture of semiconductor materials to produce exceptionally fine and sharp patterns in semiconductor materials. An exemplary discussion of photolithography is contained in 1 S. Wolf & R. Tauber, Silicon Processing for the VLSI Era 407 (1986). Additionally, the general and basic principles of photolithography are well understood in this art. A short summary of this discussion follows as an aid to the reader.

A typical photolithography process begins by coating a clean flat substrate with a thin layer of photoresist by spin coating, spraying, or immersion. “Photoresist” is the term used to describe any one of a number of chemical substances that exhibit different chemical characteristics (e.g., becomes polymerized or depolymerized) when exposed to electromagnetic radiation (e.g. light). The photoresist is allowed to dry and is then exposed to visible light or near ultraviolet radiation through a photomask. The photomask contains features that are either opaque or transparent with respect to the exposure frequencies and that define the pattern to be created in the photoresist layer. If the exposed regions of the photoresist (the areas under the transparent portion of the photomask) are soluble, a positive image of the photomask is produced in the resist. In such cases the photoresist is referred to as a “positive” resist. If the non-exposed regions (the areas under the opaque portion of the photomask) are soluble, a negative image of the photomask is produced in the resist. In such cases the photoresist is referred to as a “negative” resist.

The depolymerized (i.e., soluble) portions of the photoresist are removed using a suitable solvent (e.g., acetone) while the polymerized portion remains on the substrate and acts as a barrier to etching substances or as a mask for deposition processes. When the processing is completed, the remaining photoresist is removed using another suitable solvent.

### OBJECT AND SUMMARY OF THE INVENTION

An object of this invention is to provide an improved method for depositing thin metallic films. Another object of the invention is to use photolithography to deposit thin films in patterns that are very fine and very sharp. A further object of the invention is to provide a transducer incorporating thin metallic films deposited in accordance with the invention.

Accordingly, in one aspect, the invention is a method of depositing a thin metallic film comprising depositing an etchable metal onto a substrate. A photoresist is then applied to the layer of etchable metal. Following soft-baking, the photoresist is exposed and developed thereby uncovering selected portions of the etchable metal layer. The etchable metal layer is then etched to expose the substrate. A metallic material is then deposited on the substrate by any suitable means such as sputtering or electronic beam deposition. Preferably the deposition is accomplished under conditions that eliminate or substantively prevent carbonization of the photoresist. Carbonized photoresist is often difficult to remove later in the process. In preferred embodiments, the substrate is cooled during deposition of the metallic material. After deposition, the remaining photoresist and etchable metal are removed leaving a high-resolution thin film of a metallic material.

As used herein, the term photolithographic should be understood to mean a process by which a metal is deposited in a desired pattern through a mask of photoresist and an etchable metal layer.

In a further aspect, the invention is a device such as a transducer that is fabricated in accordance with the method of the invention. Transducers such as thin film strain gauges and thermocouples are exemplary.

The foregoing, as well as other objectives and advantages of the invention and the manner in which the same are accomplished, are further specified within the following detailed description and its accompanying drawings.

### BRIEF DESCRIPTION OF THE DRAWINGS

FIGS. 1a-1f are diagrammatic cross-sectional views of a structure being fabricated in accordance with the preferred embodiments of the present invention, as well as a flow chart describing each of the steps.

FIG. 2 is a schematic of a combination strain gauge and thermocouple formed according to the invention.

FIG. 3 is a picture of a strain gauge fabricated according to the invention.

### DETAILED DESCRIPTION

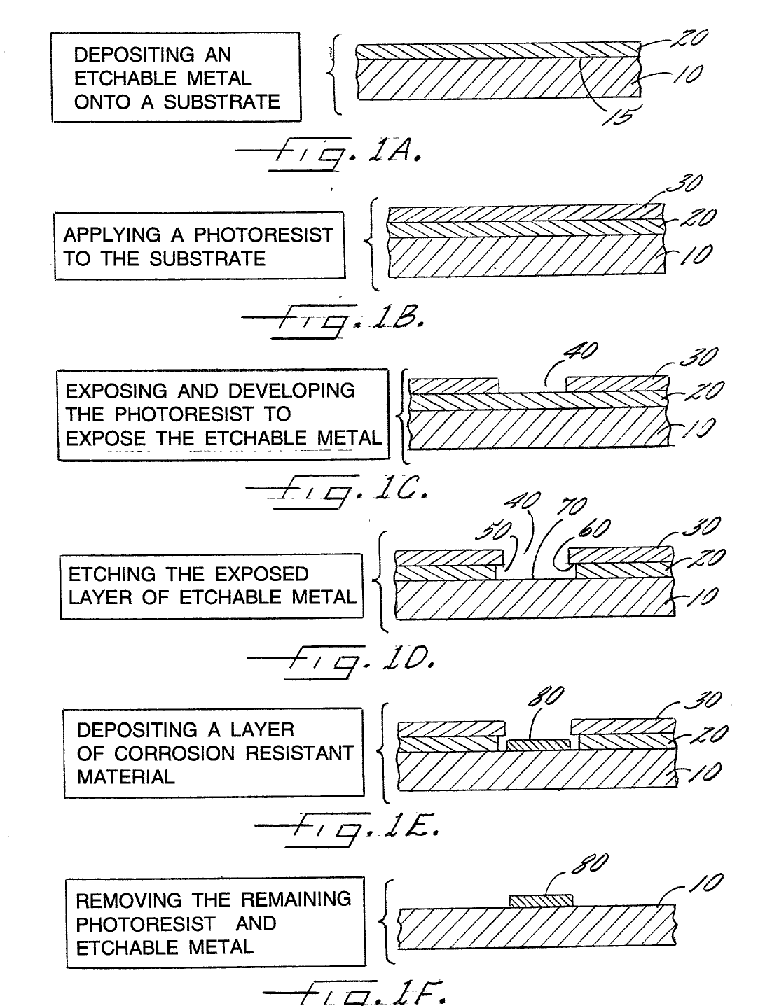

FIGS. 1a-1f show the steps utilized in depositing a thin metallic film according to the invention. In brief, the method comprises depositing an etchable metal onto a substrate; applying a photoresist to the layer of etchable metal; developing the photoresist to expose selected portions of the etchable metal layer; exposing the substrate by removing selected portions of the etchable metal layer; depositing a metallic material on the substrate while eliminating or substantially preventing carbonization of the photoresist; and removing the remaining photoresist and etchable metal. Each step is discussed in more detail below.

FIG. 1a illustrates a substrate 10 that may be any substrate required for a particular application. Although the substrate shown in FIG. 1a is flat, it may also be curved. In preferred embodiments the substrate 10 is selected from the group consisting of ceramics, metals, silicon, silicon carbide, polymer films and Group III nitrides. The term Group III nitride is used herein as it is commonly used in the semiconductor industry. In other words, it encompasses compounds comprising nitrogen and one or more of the elements listed in Group IIIB of the Periodic Table. Furthermore, the terms silicon and silicon carbide are understood to encompass doped embodiments of those materials or materials in which silicon or silicon carbide is a major component. It is to be understood that the substrate 10 includes a layer of insulating material 15 if the desired end application requires it. For example, if the invention is used to create a piezoresistive strain gauge on a metal substrate the strain gauge should be insulated from the metal substrate. This may be accomplished by depositing a layer of an insulating material on the substrate 10 prior to depositing the etchable metal layer. Suitable insulating materials include but are not limited to insulating oxides (e.g., aluminum oxide), insulating glass, insulating ceramics and insulating polymers.

Referring again to FIG. 1a, a thin layer of an etchable metal 20 is deposited upon the substrate 10. The etchable metal 20 may be any metal that may be etched and removed from the surface of substrate 10. In preferred embodiments the etchable metal 20 is selected from the group consisting of aluminum, nickel and copper. Copper is most preferred because it etches quickly and uniformly.

The etchable metal 20 may be deposited on the substrate using any conventional method such as sputter deposition. Such methods are well known to those skilled in the art and may be incorporated into the practice of the invention without undue experimentation. Accordingly, such methods will not be described herein in detail.

In preferred embodiments, the layer of etchable metal 20 is deposited by sputter deposition. In a particularly preferred embodiment, a layer of copper is sputter deposited inside a vacuum chamber. The deposition should occur under conditions that do not damage the substrate. If the deposition of the etchable metal generates an amount of heat sufficient to damage the substrate, the substrate may be placed in a cooled substrate holder. Such holders are well known to those skilled in the art and are commercially available or can be constructed without undue experiment. For example, Applicant employed a piece of copper with water running through it as a substrate holder on some occasions.

The thickness of the thin layer of etchable metal 20 may vary depending upon the substrate, the etchable metal, the method of removing the etchable metal, the desired thickness of the thin metallic film, the intricacy of the pattern for the thin metallic film, and the end use of the device. The etchable metal layer should be thick enough to adequately protect the substrate but not of a thickness that will hinder physical removal of the layer or unduly lengthen the time for removing the layer. In preferred embodiments the thin layer of etchable metal 20 is made of copper and is between 0.1 microns and 10 microns thick, most preferably between 0.5 microns and 6 microns thick.

Referring now to FIG. 1b, a layer of photoresist 30 is applied to the thin layer of etchable metal 20. The photoresist may be either a negative resist or a positive resist but a positive resist is preferred. The photoresist may likewise be deposited using conventional techniques such as spin depositing. In one application of the method according to the invention, a positive resist commercially available from Shipley Corporation under the tradename Microposit 1818 is deposited by dripping it onto a substrate rotating at approximately 3500 rpm for approximately 30 seconds. After application, the photoresist is softbaked in a conventional fashion. Those skilled in the art recognize that the conditions under which a photoresist is applied, softbaked and ultimately removed determine a number of parameters in subsequent steps in the process. Accordingly, the exact photoresist processing conditions used in the practice of the invention may vary, but those of skill in the art will be able to practice the invention without undue experimentation.

Spinning the photoresist is the preferred method when the substrate is capable of spinning. For larger or curved substrates that are unsuitable for spinning, the photoresist may be applied by dripping it on the substrate and spreading it with a compressed gas such as nitrogen. Any other suitable method known to those skilled in the art may also be employed.

The softbaked photoresist layer 30 is masked, exposed and developed in a conventional manner. If the substrate is flat conventional glass exposure masks may be used. If curved substrates are employed a pliable exposure mask that can be closely fitted to the substrate should be used. Such masks are commercially available from Circuit CAD Corp. of Dayton, Ohio. These masks are very similar to photography negatives and may be laminated to curved structures.

Developing the photoresist 30 exposes desired portions of the etchable metal layer 30 in a pattern corresponding to the pattern of the exposure mask. This pattern is schematically represented by openings 40 in FIG. 1c. Development of the photoresist also provides the first opportunity to check the integrity of the ultimate pattern for the thin layer of metallic material. If the pattern is flawed, the photoresist is easily removed and reapplied.

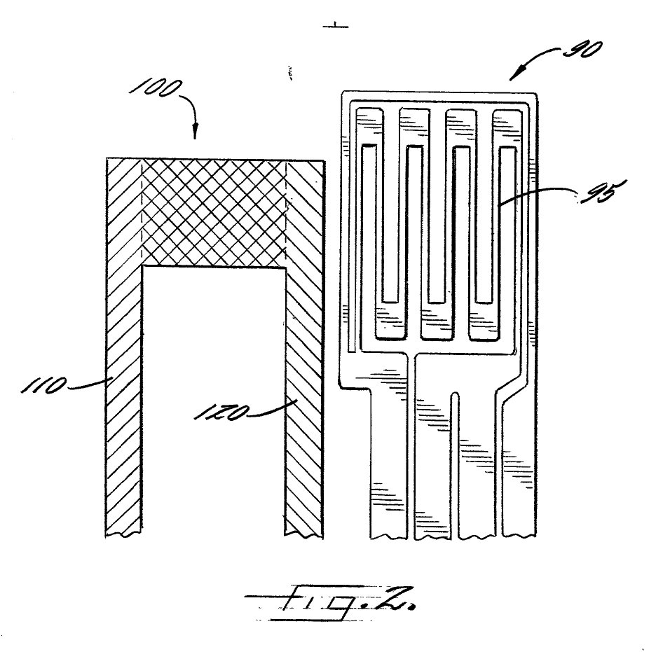

The photoresist openings 40 expose the underlying layer of etchable metal 20. Referring now to FIG. 2d, Selected portions of the etchable metal layer 20, roughly corresponding to the photoresist openings 40, are then removed to create openings 50 which expose the surface 70 of the substrate 10 (of, if required, the insulating layer 15). The exposed surface 70 represents the area where the thin film of metallic material is deposited. The selected portions of the etchable metal layer 20 may be removed using conventional etching techniques such as chemical etching. In preferred embodiments the etchable metal layer 20 is etched using conventional chemical etchants such as nitric acid. In a particular preferred embodiment the etchable metal layer 20 is formed from copper and is removed using a 50/50 by volume solution of nitric acid and water. The removal of the etchable metal layer provides a second opportunity to check the integrity of the desired thin film pattern.

In most instances, the removal of the metal layer 20 will occur in a somewhat isotropic manner, meaning the chemical etchant removes the layer in all directions. This creates a slight undercutting of the photoresist which expedites removal of unwanted material later in the process. The slight undercutting is represented by numeral 60 in FIG. 1d.

After the desired portions of the substrate 10 are exposed, a metallic material 80 is deposited on the substrate as shown in FIG. 1e. Any suitable method such as sputtering or electronic beam deposition may be used to deposit the metallic material. Preferably, the metallic material is deposited in a manner to eliminate or substantially prevent carbonization of the photoresist. Carbonizing the photoresist makes it difficult to remove. Thus, reducing the heat generated by the deposition aids in the practice of the invention. Heat may be reduced by physically separating the sputter target from the substrate or by sputtering at low power levels. As used herein the term low power sputtering means sputtering using power outputs sufficient to deposit the metal but below that which would create heat sufficient to carbonize the photoresist. In preferred embodiments the low power sputtering of the metallic material 80 utilizes no more than 0.16 W/cm². Higher power levels may be possible with greater heat removal from the substrate.

The metallic material 80 may be any material capable of sputter deposition including any of the metals traditionally viewed as corrosion resistant. In preferred embodiments the metallic material 80 is selected from the group consisting of platinum, palladium, rhodium, silver, gold, titanium, tungsten, chromium and alloys thereof. Platinum and gold are most preferred.

Theoretically, there is no upper boundary on the thickness of the layer of metallic material 80. The primary limiting factor on thickness is size of the equipment used in implementing the method according to the invention. Those practicing the invention, however, should be aware that obtaining thicker layers of metallic material 80 generally requires thicker etchable metal layers and thicker photoresist. Photoresist typically becomes syrupy and difficult to use in thicker applications. In most commercial applications the layer of metallic material 80 will be thin; on the order of between 0.1 microns and 10 microns thick, preferably between 0.5 microns and 6 microns thick.

Preferably, the substrate 10 is cooled during the deposition of the metallic material 80. The cooling may be conducted using a commercially available cooling substrate holder or a water-cooled substrate holder (not shown) such as those described previously. It should be understood that other methods of cooling are also encompassed by the invention. The cooling of the substrate during deposition further reduces carbonizing of the photoresist.

After deposition of the metallic material 80, the remaining photoresist 30 and the remaining etchable metal layer 20 are removed to leave a substrate 10 having a thin layer of metallic material 80 as shown in FIG. 1f.

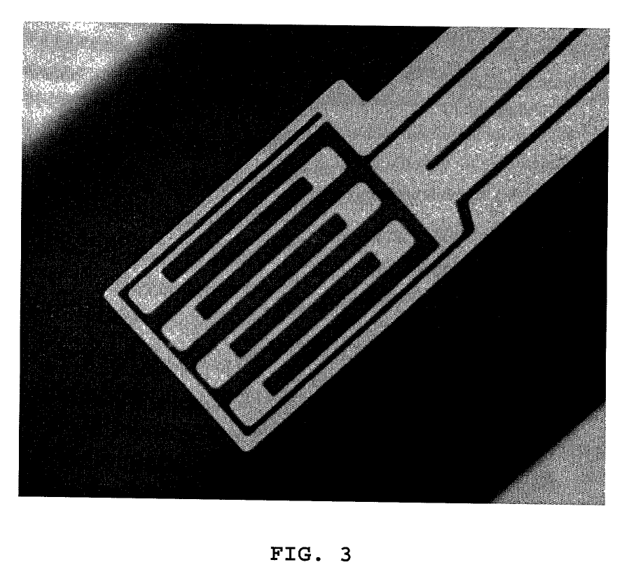

In one particular embodiment, the method according to the invention may be used to manufacture minute devices with extreme precision. One such device would be a strain gauge 90 of the type schematically shown in FIG. 2. The strain gauge 90 comprises a meandering arrangement of grid lines 95 where the grid lines comprise a thin film of photolithographicly deposited metal. In preferred embodiments, the metal is platinum or gold. A photograph of a platinum strain gauge 1.4 micron thick and manufactured according to the invention is shown in FIG. 3.

The invention also encompasses other thin film devices and transducers such as thermocouples. An exemplary thermocouple 100 is shown in FIG. 2. The thermocouple 100 comprises first and second elongated thin metallic films, 110 and 120 respectively, deposited one on top of the other as is conventionally known. Conventionally the first and second thin metallic films are of different materials such as platinum and gold.

Devices formed according to the invention may be extremely small. Precise films 100 microns wide are readily fabricated according to the invention. Precise films with widths smaller than 50 microns and smaller than 10 microns are well within the capabilities of the invention.

In the drawings and the specification, typical embodiments of the invention have been disclosed. Specific terms have been used only in a generic and descriptive sense, and not for purposes of limitation. The scope of the invention is set forth in the following claims.

That which is claimed is:

1. A method of depositing a thin metallic film comprising:
a. depositing a layer of etchable metal onto a substrate;
b. applying a photoresist to the etchable metal layer;
c. developing the photoresist to expose selected portions of the etchable metal layer;
d. etching the exposed portions of the etchable metal layer to expose selected portions of the substrate;
e. depositing a metallic material on the exposed substrate while substantially preventing carbonization of the photoresist during deposition of the metallic material;
f. removing the remaining photoresist; and
g. removing the remaining etchable metal layer.

2. A method according to claim 1 wherein the etchable metal is selected from the group consisting of copper, aluminum and nickel.

3. A method according to claim 1 wherein the etchable metal is copper.

4. A method according to claim 1 wherein the photoresist is a positive photoresist.

5. A method according to claim 1 wherein the etching step comprises chemical etching.

6. A method according to claim 5 wherein the etching step comprises chemical etching with a nitric acid solution.

7. A method according to claim 1 wherein the deposition of the metallic material is accomplished by sputtering.

8. A method according to claim 1 wherein the step of eliminating or substantially preventing carbonization of the photoresist comprises using low power sputtering.

9. A method according to claim 8 wherein the sputtering occurs at a power level of no more than 0.16 W/cm².

10. A method according to claim 1 wherein the metallic material is selected from the group comprising platinum, palladium, rhodium, gold, silver, titanium, tungsten, chromium, and alloys thereof.

11. A method according to claim 1 wherein the step of substantially preventing carbonization of the photoresist comprises cooling of the substrate during the metallic deposition step.

12. A method according to claim 11 wherein the step of substantially preventing carbonization of the photoresist comprises placing the substrate in contact with a cooled substrate holder during deposition of the metallic material.

13. A method according to claim 1 wherein the substrate is selected from the group comprising ceramics, metals, silicon, silicon carbide, polymer films, and Group III nitrides.

14. A method according to claim 1 further comprising depositing a layer of insulating material on the substrate prior to depositing the layer of etchable metal.

15. A method according to claim 1 wherein the substrate is an insulating material.

16. A method according to claim 14 wherein the insulating layer is selected from the group consisting of insulating oxides, insulating glass, insulating ceramics and insulating polymers.

17. A method according to claim 15 wherein the insulating material is selected from the group consisting of insulating oxides, insulating glass, insulating ceramics and insulating polymers.

18. A method of depositing a thin metallic film comprising:
a. depositing a layer of copper onto a substrate;
b. applying a positive photoresist to the copper layer;
c. softbaking the photoresist;
d. exposing the photoresist through a photomask;
e. developing the photoresist to expose a portion of the copper layer;
f. chemically etching the exposed copper layer with nitric acid to expose a portion of the substrate;
g. depositing a metallic material on the exposed substrate while substantially preventing photoresist carbonization during deposition of the metallic material;
h. removing the remaining photoresist; and
i. removing the remaining copper.

19. A method according to claim 18 wherein the metallic material is deposited by sputtering.

20. A method according to claim 19 wherein the sputtering occurs at a power level of no more than 0.16 W/cm2.

21. A method according to claim 18 wherein said metallic material is selected from the group comprising platinum, palladium, rhodium, gold, silver, titanium, tungsten, chromium, and alloys thereof.

22. A method according to claim 18 further comprising cooling the substrate during deposition of the metallic material.

23. A method according to claim 18 wherein the substrate is selected from the group comprising ceramics, metals, silicon, silicon carbide, polymer films, and Group III nitrides.

24. A method according to claim 18 further comprising depositing a layer of insulating material on the substrate prior to depositing the layer of copper.

25. A method according to claim 18 wherein the substrate is an insulating material.

26. A method according to claim 24 wherein the insulating layer is selected from the group consisting of insulating oxides, insulating glass, insulating ceramics and insulating polymers.

27. A method according to claim 25 wherein the insulating material is selected from the group consisting of insulating oxides, insulating glass, insulating ceramics and insulating polymers.

28. A strain gauge comprising a meandering arrangement of grid lines, said grid lines comprising a thin film of a photolithographically deposited metal.

29. A strain gauge according to claim 28 wherein the deposited metal is platinum.

30. A strain gauge according to claim 28 wherein the deposited metal is gold.

31. A strain gauge according to claim 28 further comprising an insulating layer in contact with said deposited metal.

32. A strain gauge according to claim 31 wherein said insulating layer is selected from the group consisting of insulating oxides, insulating glass, insulating ceramics and insulating polymers.

33. A strain gauge according to claim 32 wherein said insulating material is aluminum oxide.

34. A strain gauge according to claim 28 wherein the strain gauge is in contact with a curved substrate.

35. A strain gauge according to claim 28 wherein said grid lines are less than 100 microns wide.

36. A strain gauge according to claim 28 wherein said grid lines are less than 50 microns wide.

37. A strain gauge according to claim 28 wherein said grid lines are less than 10 microns wide.

38. A thin film thermocouple comprising:
a substrate;
a first thin film of photolithographically deposited metal on said substrate; and
a second thin film of a photolithographically deposited metal on said substrate;
said first and second films arranged to form a thermocouple.

39. A thin film thermocouple according to claim 38 further comprising a layer of insulating material between said substrate and said first and second thin films.

40. A thermocouple according to claim 39 wherein the insulating layer is selected from the group consisting of insulating oxides, insulating glass, insulating ceramics and insulating polymers.

41. A thermocouple according to claim 40 wherein said insulating layer is aluminum oxide.

42. A thermocouple according to claim 38 wherein the metal used for one of the thin films is platinum.

43. A thermocouple according to claim 38 wherein the metal used for one of the thin films is gold.

44. A thermocouple according to claim 38 wherein the substrate is curved.

45. A thermocouple according to claim 38 wherein said thermocouple comprises thin film structures less than 100 microns wide.

46. A thermocouple according to claim 38 wherein said thermocouple comprises thin film structures less than 50 microns wide.

47. A thermocouple according to claim 38 wherein said thermocouple comprises thin film structures less than 10 microns wide.

48. A thermocouple according to claim 38 wherein said substrate is an insulating material.

49. A thermocouple according to claim 48 wherein said insulating material is selected from the group consisting of insulating oxides, insulating glass, insulating ceramics and insulating polymers.

50. A transducer manufactured according to the method of claim 1.

51. A transducer manufactured according to the method of claim 18.
